(19) United States
(12) Patent Application Publication
(10) Pub. No.: US 2008/0078995 A1
(43) Pub. Date: Apr. 3, 2008

(54) CHIP STRUCTURE

(75) Inventor: CHUNG-PANG CHI, TAINAN COUNTY (TW)

Correspondence Address: J C PATENTS, INC., 4 VENTURE, SUITE 250, IRVINE, CA, 92618, US

(73) Assignees: CHIPMOS TECHNOLGIES INC., HSINCHU (TW); CHIPMOS TECHNOLOGIES (BERMUDA) LTD., HAMILTON HM12 (BM)

(21) Appl. No.: 11/550,288

(22) Filed: Oct. 17, 2006

(30) Foreign Application Priority Data
Jul. 17, 2006 (TW) 95126005

(51) Int. Cl. H01L 23/58; H01L 29/10

(52) U.S. Cl. 257/48

(57) ABSTRACT

A chip structure including a substrate, a plurality of chip bonding pads and a plurality of test-bonding-pad sets is provided. The substrate has an active surface and the chip bonding pads are disposed on the active surface. At least part of the chip bonding pads is arranged along a first line. The test-bonding-pad sets are disposed on the active surface and arranged along a second line, wherein the first line is parallel to the second line and the pitches between neighboring test-bonding-pad sets are the same. Each test-bonding-pad set has a plurality of test bonding pads. The test bonding pads are electrically connected to the chip bonding pads arranged along the first line. The distances between the test bonding pads of each test-bonding-pad set and the first line are different. Accordingly, there is no increase in the cost for electrical testing said chip structure.

### CROSS-REFERENCE TO RELATED APPLICATION

This application claims the priority benefit of Taiwan application serial no. 95126005, filed on Jul. 17, 2006. All disclosure of the Taiwan application is incorporated herein by reference.

### BACKGROUND OF THE INVENTION

1. Field of the Invention

The present invention relates to a chip structure, and more particularly, to a chip structure with a plurality of test bonding pads.

2. Description of Related Art

In the manufacturing of semiconductor devices, the production of integrated circuits (IC) is mainly divided into three stages: the integrated circuit design stage, the integrated circuit fabrication stage and the integrated circuit packaging stage.

In the fabrication of integrated circuits, chips are formed by performing a series of steps including wafer processing, integrated circuit forming, electrical testing and wafer sawing. The wafer has an active surface where active devices are formed. After forming the required integrated circuits on the wafer, a plurality of bonding pads is disposed on the active surface of the wafer so that the chips cut out from the wafer can be electrically connected with an external carrier through these bonding pads.

The process of testing the chips while the chips are in the wafer state is called wafer sorting. The wafer sorting is carried out through a temporarily established electrical contact between the chips and an automated testing apparatus. The wafer sorting is an important test of the integrated circuit design and function so that the really good chips are selected before performing the subsequent processes of separating and packaging the chips.

FIG. 1A is a top view of a conventional chip structure and FIG. 1B is a side view of the chip structure in FIG. 1A. The conventional structure 100 includes a substrate 110, a plurality of chip bonding pads 120, a passivation layer 130 and a plurality of bumps 140. The substrate 110 has an active surface 112, and the chip bonding pads 120 are disposed on the active surface 112 in a ring-like arrangement. The passivation layer 130 covers the active surface 112 but exposes the chip bonding pads 120. In addition, the bumps 140 are disposed on the chip bonding pads 120.

However, due to the trend of miniaturizing or increasing the level of integration of devices within the chip structure 100, the pitches between neighboring chip bonding pads 120 are getting smaller. To perform an electrical testing of the chip structure 100 (in the wafer sorting stage before the singulation of the chip structure 100), the pitches between neighboring testing contacts (not shown) of the testing apparatus (not shown) cannot be reduced in correspondence to same extent as the pitches between neighboring chip bonding pads 120. Hence, the testing contacts (not shown) are not able to contact the bumps 140 on the chip bonding pads 120 and successfully perform an electrical testing of the chip structure 100. As a result, the shortening of the pitches between neighboring chip bonding pads 120 increases difficulties of the electrical testing of the chip structure 100, and thereby increases the cost of the electrical testing.

### SUMMARY OF THE INVENTION

Accordingly, at least one objective of the present invention is to provide a chip structure having a smaller pitch between neighboring chip bonding pads and yet allowing an electrical testing to be performed using an existing testing apparatus.

To achieve these and other advantages and in accordance with the purpose of the invention, as embodied and broadly described herein, the invention provides a chip structure including a substrate, a plurality of chip bonding pads and a plurality of test-bonding-pad sets. The substrate has an active surface and the chip bonding pads are disposed on the active surface. At least part of the chip bonding pads is arranged along a first line. The test-bonding-pad sets are disposed on the active surface and arranged along a second line, wherein the first line is parallel to the second line and the pitches between neighboring test-bonding-pad sets are the same. Each test-bonding-pad set has a plurality of test bonding pads. The test bonding pads are electrically connected to the chip bonding pads arranged along the first line. The distances between the test bonding pads of each test-bonding-pad set and the first line are different.

Accordingly, because each test-bonding-pad set in the chip structure of the present invention has test bonding pads, the process of electrically testing the chip structure can still be achieved through electrical contacts of the testing apparatus with the test bonding pads though the pitches between chip bonding pads get smaller. Therefore, the existing testing apparatus can still be used to perform an electrical testing of the chip structure in the present invention without increasing any electrical testing cost.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view of a conventional chip structure.

FIG. 1B is a side view of the chip structure in FIG. 1A.

FIG. 2A is a top view of a chip structure according to a first embodiment of the present invention.

FIG. 2B is a side view of the chip structure in FIG. 2A.

FIG. 3 is a top view of a chip structure according to a second embodiment of the present invention.

FIG. 4 is a top view of a chip structure according to a third embodiment of the present invention.

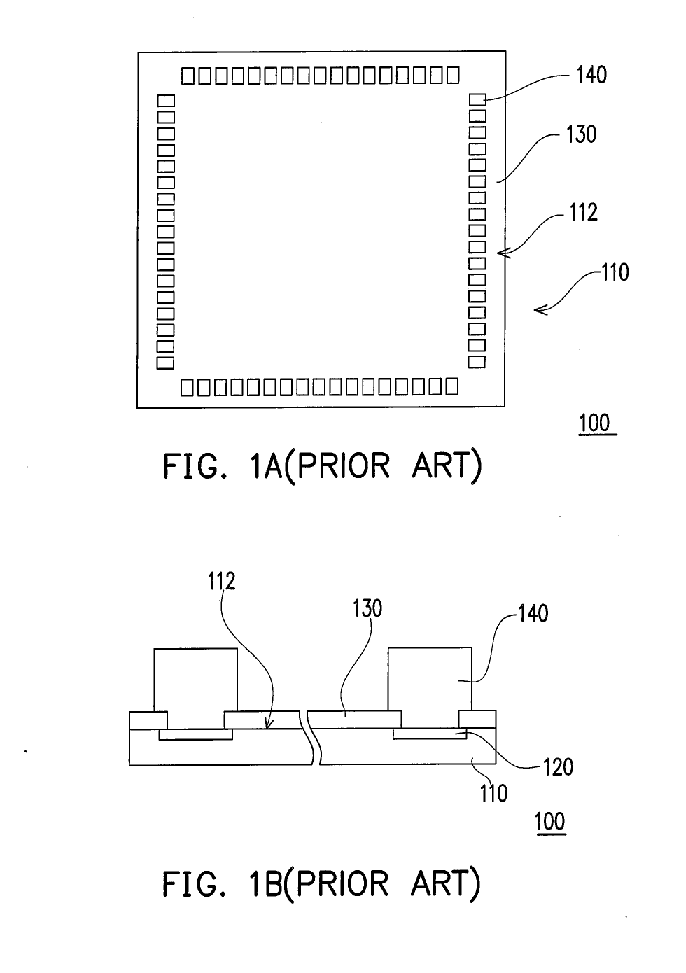

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

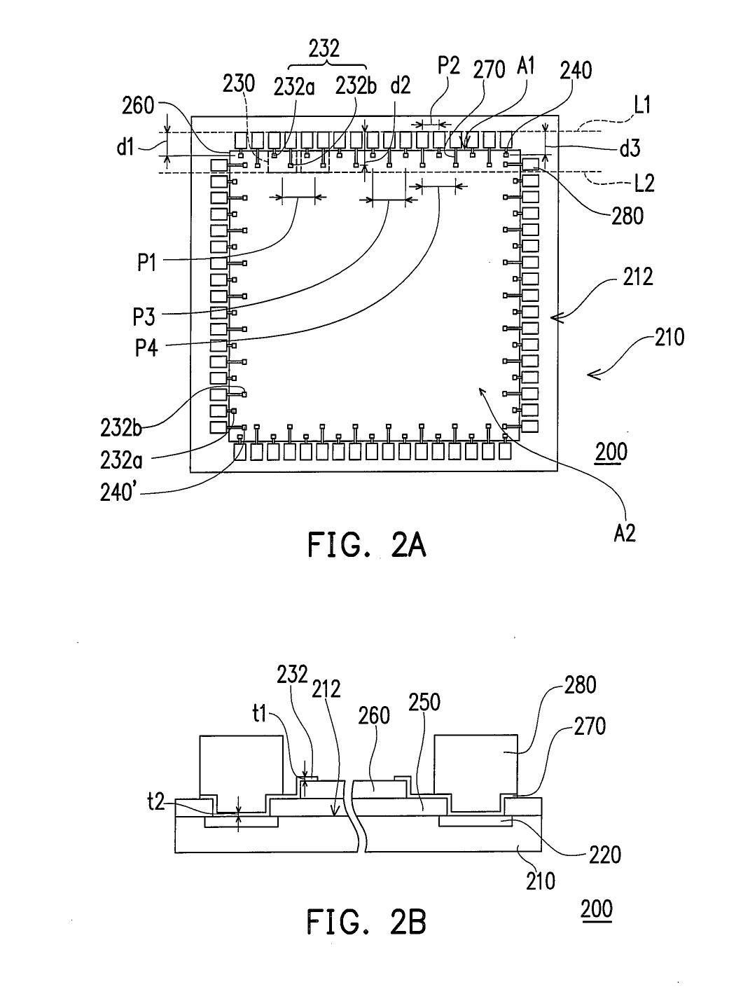

FIG. 2A is a top view of a chip structure according to a first embodiment of the present invention. FIG. 2B is a side view of the chip structure in FIG. 2A. As shown in FIGS. 2A and 2B, the chip structure 200 in the first embodiment includes a substrate 210, a plurality of chip bonding pads 220 and a plurality of test-bonding-pad sets 230. The substrate 210 has an active surface 212. The chip bonding pads 220 are disposed on the active surface 210. At least part of the chip bonding pads 220 are arranged along a first line L1.

The test-bonding-pad sets 230 are disposed on the active surface 212 and arranged along a second line L2. The first line L1 is parallel to the second line L2. Furthermore, the pitches P1 between neighboring test-bonding-pad sets 230 are identical. Each test-bonding pad set 230 has a plurality of test bonding pads 232 (only two is shown in FIG. 2A). The test bonding pads 232 are electrically connected to the chip bonding pads 232 arranged along the first line L1. Moreover, the distances d1, d2 between the test bonding pads 232 in each test-bonding-pad set 230 and the first line L1 are different.

In the first embodiment, test bonding pads 232 of each test-bonding-pad set 230 includes a first test bonding pad 232a and a second test bonding pad 232b. The distance d1 between the first test bonding pad 232a and the first line L1 can be smaller than the distance d2 between the second test bonding pad 232b and the first line L1. In addition, the chip bonding pads 220 can be arranged in the form of a ring and disposed in a plurality of side regions A1 (a total of four side regions are shown in FIG. 2A) on the active surface 212. The test-bonding-pad sets 230 can be disposed inside an interior region A2 surrounded by the chip bonding pads 220.

According to the relative position of the chip structure 200 in FIG. 2A, in the side region A1 on the uppermost edge of the chip structure 200, the chip structure 200 further includes a third test bonding pad 240. The third test bonding pad 240 is disposed on the active surface 212 adjacent to one of the two test-bonding-pad sets 230 at the farthest end. In the first embodiment, the third test bonding pad 240 is adjacent to the rightmost test-bonding-pad set 230. The third test bonding pad 240 is electrically connected to one of the chip bonding pads 220 arranged along the first line. L1. Furthermore, the distance d3 between the third test bonding pad 240 and the first line L1 is equal to the distance d1 between the first test bonding pad 232a and the line L1. Moreover, the third test bonding pad 240 is adjacent to the second test bonding pad 232b.

In other words, in the side region A1 at the uppermost edge of the active surface 212, the first test bonding pads 232a, the second test bonding pads 232b and the third test bonding pad 240 are alternately disposed and arranged to form a saw-tooth shape. As shown in FIG. 2A, the first test bonding pads 232a and the third test bonding pad 240 are disposed in parallel to the second line L2 to form a row. Similarly, the second test bonding pad 232b are also disposed in parallel to the second line L2 to form a row.

When touching the chip bonding pads 220 in the side region A1 at the uppermost edge of the active surface 212 of the chip structure 200 by the plurality of testing contacts (not shown) of the testing apparatus (not shown) to perform an electrical testing, even if the pitches P2 of neighboring chip bonding pads 220 in the side region A1 at the uppermost edge of the active surface 212 are shorter, the testing apparatus (not shown) can still test the first test bonding pads 232a and the third test bonding pad 240 through the testing contacts (not shown) first because the pitches P3 between them are significantly longer than the pitches P2. Thereafter, the second test bonding pads 232b are tested. The pitches P4 between the second test bonding pads 232b are longer than the pitches P2. In fact, the length of the pitches P3 and P4 is substantially identical to the pitches P1 between neighboring test-bonding-pad sets 230. In other words, the test-bonding-pad sets 230 in the side region A1 at the uppermost edge of the active surface 212 can still use the existing testing apparatus (not shown) to complete the electrical testing without increasing the cost.

It should be noted that the arrangement of the chip bonding pads 220 and the test-bonding-pad sets 230 in other side regions A1 of the active surface 212 and the method of testing are mostly identical to the foregoing description. Using the leftmost side region A1 of the active surface 212 as an example, the main difference is that the designer can set the position of the third test bonding pad 240′ and their relative relation in a way identical to that of the second test bonding pads 232b according to the arrangement of the test-bonding-pad sets 230. In other words, in the side region A1 at the leftmost side of the active surface 212, the first test bonding pads 232a are arranged to form a row. Similarly, the second test bonding pads 232b and the third test bonding pad 240′ are arranged to form another row. Furthermore, the first test bonding pads 232a, the second test bonding pads 232b and the third test bonding pad 240′ are alternately disposed to form a saw-tooth arrangement.

It should be noted that the designer might increase the number of test bonding pads 232 in each test-bonding-pad set 230 as long as the electrical testing of the chip structure 200 remains unaffected. In other words, the number of test bonding pads 232 (two) in each test-bonding-pad set 230 in the first embodiment is used as an example only and should by no means be used to limit the scope of the present invention.

As shown in FIG. 2B, the thickness t1 of each test bonding pad 232 in the first embodiment can be greater than or equal to 2 micron and less than or equal to 6 micron. The test bonding pads 232 can be made of gold. In addition, the chip structure 200 may further includes a first passivation layer 250 and at least a second passivation layer 260. The first passivation layer 250 covers the active surface 212 but exposes the chip bonding pads 220. The material constituting the first passivation layer includes benzo-cyclo-butene (BCB) and the material constituting the second passivation layer includes polyimide, for example. The second passivation layer 260 partially covers the first passivation layer 250 and the test bonding pads 232 are disposed on the second passivation layer 260. In the first embodiment, the second passivation layer 260 has a rectangular shape (refer to FIG. 2A).

It should be noted that the testing apparatus (not shown) need to apply a pressure on the test bonding pads 232 in order to maintain an electrical contact between the testing contacts (not shown) of the testing apparatus (not shown) and the test bonding pads 232 when electrically testing the chip structure 200. Since the second passivation layer 260 can withstand this pressure, it serves the additional function of protecting the active surface 212 of the substrate 210.

As shown in FIGS. 2A and 2B, the chip structure 200 further includes a plurality of bonding-pad connection wires 270. Using the side region A1 at the uppermost edge of the active region 212 as an example, the chip bonding pads 220 arranged along the first line L1 are electrically connected to the test bonding pads 232 through the bonding-pad connection wires 270. A part of each bonding-pad connection wire 270 is disposed on one of the chip bonding pads 220 while another part of each bonding-pad connection wire 270 is disposed on the first passivation layer 250. The remaining part of each bonding-pad connection wire 270 is disposed on the second passivation layer 260. In addition, the thickness t2 of each bonding-pad connection wire 270 can be greater than or equal to 2 microns and smaller than or equal to 6 microns. Furthermore, the bonding-pad connection wires 270 can be made of gold.

In the first embodiment, the chip structure 200 further includes a plurality of bumps 280 disposed on the chip bonding pads 220. Furthermore, each bump 280 is made of gold. The bumps 280 serve as a medium for electrically connecting the chip structure 200 to a carrier (not shown).

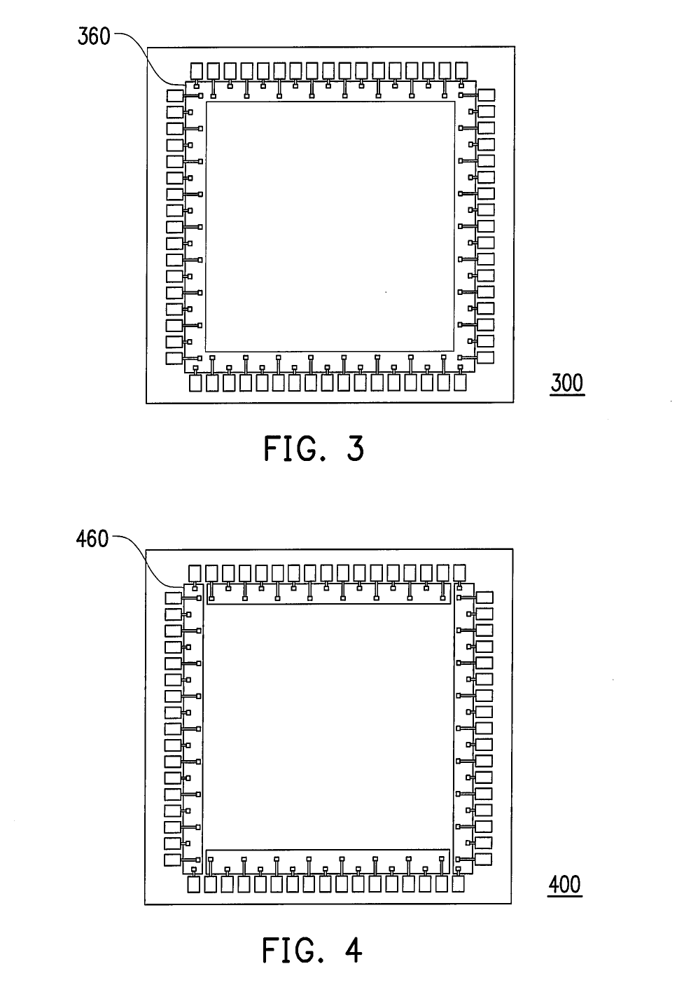

FIG. 3 is a top view of a chip structure according to a second embodiment of the present invention. The main difference between the chip structure 300 in the second embodiment and the chip structure 200 in the first embodiment is that the second passivation layer 360 of the chip structure 300 takes a ring shape. FIG. 4 is a top view of a chip structure according to a third embodiment of the present invention. The main difference between the chip structure 400 in the third embodiment and the foregoing chip structure 200 and 300 is that the second passivation layer 460 in the chip structure 400 comprises a plurality of linear strips. The total number of linear strips comprising the second passivation layers 460 in the chip structure 400 is four, for example.

In summary, because each test-bonding-pad set in the chip structure of the present invention has test bonding pads, the process of electrically testing the chip structure can be achieved through electrical contacts of the testing apparatus with the test bonding pads though the pitches between chip bonding pads get smaller. Therefore, the existing testing apparatus can still be used to perform an electrical testing of the chip structure in the present invention without increasing any electrical testing cost.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A chip structure, comprising:
a substrate having an active surface;
a plurality of chip bonding pads disposed on the active surface, wherein at least part of the chip bonding pads are arranged along a first line;
a first passivation layer covering the active surface but exposing the chip bonding pads;
at least a second passivation layer, wherein the second passivation layer partially covers the first passivation layer;
a plurality of bumps disposed on the chip bonding pads and on the first passivation layer; and
a plurality of test-bonding-pad sets disposed on the second passivation layer and over the active surface and arranged along a second line, wherein the first line is parallel to the second line, the pitches between neighboring test-bonding-pad sets are identical, each test-bonding-pad set has a plurality of test bonding pads, the test bonding pads are electrically connected to the chip bonding pads arranged along the first line, and the distances between the test bonding pads of each test-bonding-pad set and the first line are different.

2. The chip structure of claim 1, wherein the test bonding pads of each test-bonding-pad set comprise:
a first test bonding pad; and
a second test bonding pad, wherein the distance between the first test bonding pad and the first line is smaller than the distance between the second test bonding pad and the first line.

3. The chip structure of claim 2, further comprising a third test bonding pad disposed on the active surface and adjacent to one of the two test bonding pad sets at the farthest end, wherein the third test bonding pad is electrically connected to one of the chip bonding pads arranged along the first line, the distance between the third test bonding pad and the first line is identical to the distance between the first test bonding pad and the first line, and the third test bonding pad is adjacent to the second test bonding pad.

4. The chip structure of claim 2, further comprising a third test bonding pad disposed on the active surface and adjacent to one of the two test-bonding-pad sets at the farthest end, wherein the third bonding pad is electrically connected to one of the chip bonding pads arranged along the first line, the distance between the third test bonding pad and the first line is identical to the distance between the second test bonding pad and the first line, and the third test bonding pad is adjacent to the first test bonding pad.

5. The chip structure of claim 1, wherein the chip bonding pads are arranged to form a ring disposed in a plurality of side regions on the active surface.

6. The chip structure of claim 5, wherein the test-bonding-pad sets are disposed inside the area surrounded by the chip bonding pads on the active surface.

7. The chip structure of claim 1, wherein the thickness of the test bonding pads is greater than or equal to 2 microns and smaller than or equal to 6 microns.

8. The chip structure of claim 1, wherein the material constituting the test bonding pads comprises gold.

9-10. (canceled)

11. The chip structure of claim 1, wherein the shape of the second passivation layer comprises a rectangular shape, a ring shape or a strip shape.

12. The chip structure of claim 1, wherein the material constituting the second passivation layer comprises polyimide.

13. The chip structure of claim 1, further comprising a plurality of bonding-pad connection wires such that the chip bonding pads along the first line are electrically connected to the test bonding pads through the bonding-pad connection wires respectively, and a part of each bonding-pad connection wire is disposed on one of the Chip bonding pads, another part of each bonding-pad connection wire is disposed on the first passivation layer and the remaining part of each bonding-pad connection wire is disposed on the second passivation layer.

14. The chip structure of claim 13, wherein the thickness of the bonding-pad connection wires is greater than or equal to 2 microns and is smaller than or equal to 6 microns.

15. The chip structure of claim 13, wherein the material constituting the bonding-pad connection wires comprises gold.

16 (canceled)

17. The chip structure of claim 1, wherein the material constituting the bumps comprises gold.
